(19) United States
(12) Patent Application Publication
(10) Pub. No.: US 2007/0194466 A1
(43) Pub. Date: Aug. 23, 2007

(54) Overlay measurement mark and pattern formation method for the same

(75) Inventor: Hidenori Yamaguchi, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 11/703,820

(22) Filed: Feb. 8, 2007

(30) Foreign Application Priority Data
Feb. 9, 2006 (JP) 2006-32473

(51) Int. Cl. H01L 23/544

(52) U.S. Cl. 257/797

(57) ABSTRACT

Fine projection patterns are added to each side of a base mark pattern of an overlay measurement mark. Thus, film separation in the overlay measurement mark can be prevented.

### BACKGROUND OF THE INVENTION

1. Field of the Invention

The present invention relates to an overlay measurement mark for measuring overlay positional displacement of a circuit pattern in a lithography process to manufacture a semiconductor device. The present invention also relates to a pattern formation method for such an overlay measurement mark.

2. Description of the Related Art

Recently, semiconductor devices have made remarkable progress. For example, integration of semiconductor devices in a dynamic random access memory (DRAM) has doubled approximately every 12 months to 18 months. Optical lithography technology contributes to this high integration. The optical lithography technology is used to form fine circuit patterns constituting a device and accurately overlay a plurality of layers in which fine circuit patterns are formed. Fineness in the optical lithography has heretofore been achieved by shortening a wavelength of a light source. Further, the overlay technology has made progress through improvement of an aligner and introduction of an overlay measurement apparatus. However, an overlay precision finally depends on a device manufacturing process. Accordingly, an overlay precision is influenced by a design of a structure of an overlay measurement mark and an optimal selection of overlaid portions (alignment tree).

The transcription positional information and precision can be obtained by using overlay measurement marks formed on a wafer and on a reticle. An aligner called a stepper is used for optical lithography. First, a reticle of the aligner and a wafer are set in position. Then, the wafer is aligned with the reticle, moved in an X direction and a Y direction, and subjected to exposure. In this case, positional displacement may be caused in the X direction, the Y direction, and a rotation direction. Accordingly, overlay measurement marks generally have such patterns so that their positional displacement can be measured in a horizontal direction and a vertical direction.

For example, Japanese laid-open patent publication No. 62-092440 (Patent Document 1) discloses that a concave or convex pattern having a small width is formed as a reference mark on a principal plane of a semiconductor substrate so as to sharpen the intensity of reflection light in this manner, erroneous recognition is prevented. Japanese laid-open patent publication No. 04-159706 (Patent Document 2) discloses that each of a reference mark and an alignment mark has an uneven rectangular shape and that small spaces between the reference mark and the alignment mark and large spaces between the reference mark and the alignment mark are used as measurement points, respectively. Japanese laid-open patent publication No. 2002-313698 (Patent Document 3) discloses that an alignment mark is disposed so as to face reference marks arranged in parallel to each other and provided with recesses and projections so as to prevent erroneous recognition. Japanese laid-open patent publication No. 08-321534 (Patent Document 4) discloses that each of a reference mark and an alignment mark has a comblike shape with teeth arranged at doubled intervals so that the reference mark and the alignment mark can be used in a plurality of processes. Japanese laid-open patent publication No. 09-129711 (Patent Document 5) discloses that an alignment pattern has angle patterns provided on portions of its sides so, as to prevent epitaxial pattern shift and distortion.

A basic conventional overlay measurement mark will be described below with reference to FIGS. 1 to 2C. FIG. 1 is a plan view showing an overlay measurement mark, and FIGS. 2A to 2C are cross-sectional views showing a process of forming the overlay measurement mark.

In order to manufacture a semiconductor device, a contact hole is first formed in an insulating film 2. A conductive film is deposited on the insulating film 2 and filled into the contact hole so as to form a contact plug. An upper surface of the conductive film is flattened by CMP. Further, another insulating film is deposited thereon, and a conduction contact with the contact plug is opened in the insulating film. In this case, a reference mark is formed by the first contact process while an overlay mark to be measured is formed by the second conduction contact process. Depending upon a semiconductor device manufacturing process, the overlay mark to be measured may be formed as a convex mark, which is produced by digging the vicinity of the overlay mark as shown in FIGS. 1 to 2C, or formed as a concave mark (dug shape), which is produced by removing the deposited portion of the reference mark.

As shown in FIG. 2A, a contact hole is opened in an insulating film 2 deposited on a principal plane of a semiconductor substrate 1 so as to form a rectangular reference mark 3. As shown in FIG. 2B, a conductive film 4 as a contact plug is deposited and filled into the contact hole. An upper surface of the conductive film 4 is flattened by an etch-back method or chemical mechanical polishing (CMP) until the surface of the conductive film 4 is located at the height of the insulating film 2. In this case, if the reference mark pattern 3 has the same line width as an internal circuit pattern, the reference mark pattern 3 is fully filled with the conductive film 4. From this point of view, the line width of the contact hole as the reference mark pattern 3 is designed to be slightly greater than the width of an internal circuit pattern. Thereafter, an interlayer insulating film is deposited on the insulating film 2. As shown in FIG. 2C, a conduction contact with the contact plug is opened in the interlayer insulating film so as to form an overlay mark 5 to be measured. The amount of positional displacement between the overlay reference mark 3 and the overlay mark 5 is measured to calculate an overlay correction value upon exposure.

As described above, the reference mark pattern has a limitation in line width. If the reference mark pattern 3 has a small line width, the reference mark pattern 3 is fully filled with the conductive film 4. When the reference mark pattern 3 is fully filled with the conductive film 4, a mark signal strength required for mark measurement cannot be obtained. As a result, a desired overlay precision cannot be obtained. Accordingly, the line width of the contact hole as the reference mark pattern 3 is designed to be greater than the width of an internal circuit pattern. However, if the reference mark pattern 3 has a large line width, the conductive film 4 on sidewalls of the insulating film 2 is separated from the reference mark pattern 3 during a chemical mechanical polishing (CMP) process or a cleaning process. Further, in a case of an overlay measurement mark formed by a separate process to eliminate its separation, a desired overlay precision cannot be obtained due to an overlay correction.

### SUMMARY OF THE INVENTION

As described above, in a process flow of manufacturing recent fine semiconductor devices, it becomes evident that a film remaining on sidewalls of a reference mark is problematically separated during a flattening process with CMP or an etch-back method. The aforementioned patent documents have proposed various reference marks and overlay marks to be measured. However, those patent documents have not recognized a problem of film separation in a reference mark. Therefore, no suitable methods are disclosed in order to solve the problem of film separation. The present invention provides an overlay measurement mark and a pattern formation method for an overlay measurement mark in order to solve the problem of film separation.

As described above, film separation occurs in a reference mark of an overlay measurement mark according to recent progress of finer semiconductor devices. Due to the film separation, overlay positional displacement cannot be measured precisely. Thus, a desired overlay precision cannot be obtained.

The present invention has been made in view of the above drawbacks. It is, therefore, an object of the present invention to provide an overlay measurement mark and a pattern formation method for an overlay measurement mark which can prevent film separation in a reference mark of an overlay measurement mark and measure overlay positional displacement precisely.

In order to resolve the above problem, the present invention basically adopts the following technology. As a matter of course, the present invention covers applied technology in which various changes and modifications are made therein without departing from the spirit of the present invention.

According to a first aspect of the present invention, an overlay measurement mark includes a base mark pattern and a projection pattern in addition to the base mark pattern.

The projection pattern may be held in contact with the base mark pattern.

The projection pattern may have a width not more than two times a thickness of a film to be deposited in a deposition process after patterning.

The projection pattern may comprise a rectangular pattern provided so as to intersect the base mark pattern.

The projection pattern may comprise a triangular pattern having a base provided on a portion of one side of the base mark pattern.

The projection pattern may comprise a semicircular pattern having a diameter passing through a portion of one side of the base mark pattern.

The base mark pattern may include a plurality of base mark pattern portions, and the projection pattern may interconnect adjacent base mark pattern portions.

According to a second aspect of the present invention, a pattern formation method for an overlay measurement mark includes a reference mark formation process of forming a reference mark including a base mark pattern and a projection pattern in addition to the base mark pattern, a deposition process of filling the projection pattern, and an overlay mark formation process of forming an overlay mark to be measured.

According to a third aspect of the present invention, a semiconductor device is manufactured by using the aforementioned overlay measurement mark and the aforementioned pattern formation method.

According to the present invention, a reference mark of an overlay measurement mark includes a fine projection pattern, so that film separation can be prevented in the overlay measurement mark. Therefore, it is possible to use an overlay reference mark having a large line width. Accordingly, it is possible to achieve a desired overlay precision with a circuit pattern formation layer in which an overlay precision is required to be maintained. Thus, the present invention can contribute to a manufacturing process of semiconductor devices such as ULSIs, which have increasingly been reduced in size and integrated to a higher degree, and can provide high-performance semiconductor devices.

The above and other objects, features, and advantages of the present invention will be apparent from the following description when taken in conjunction with the accompanying drawings which illustrate preferred embodiments of the present invention by way of example.

### BRIEF DESCRIPTION OF THE DRAWINGS

FIG. 1 is a plan view showing an overlay measurement mark in the related art;

FIGS. 2A to 2C are cross-sectional views taken along line X-X′ in FIG. 1 to show a process of forming the overlay measurement mark;

FIG. 3 is a plan view showing an overlay measurement mark according to a first embodiment of the present invention which uses rectangular patterns as projection patterns;

FIGS. 4A to 4C are cross-sectional views taken along line X-X′ in FIG. 3 to show a process of forming the overlay measurement mark;

FIG. 5 is a plan view showing a memory cell and an overlay measurement mark according to a second embodiment of the present invention;

FIGS. 6A to 6C are cross-sectional views taken along line X-X′ in FIG. 5 to show a process of forming the overlay measurement mark;

FIGS. 7A to 7C are cross-sectional views taken along line X-X′ in FIG. 5 to show a process of forming the overlay measurement mark;

FIG. 8 is a plan view showing an overlay measurement mark according to a third embodiment of the present invention which uses triangular patterns as projection patterns;

FIG. 9 is a plan view showing an overlay measurement mark using semicircular patterns as projection patterns; and

FIG. 10 is a plan view showing an overlay measurement mark using bridge-shaped patterns as projection patterns.

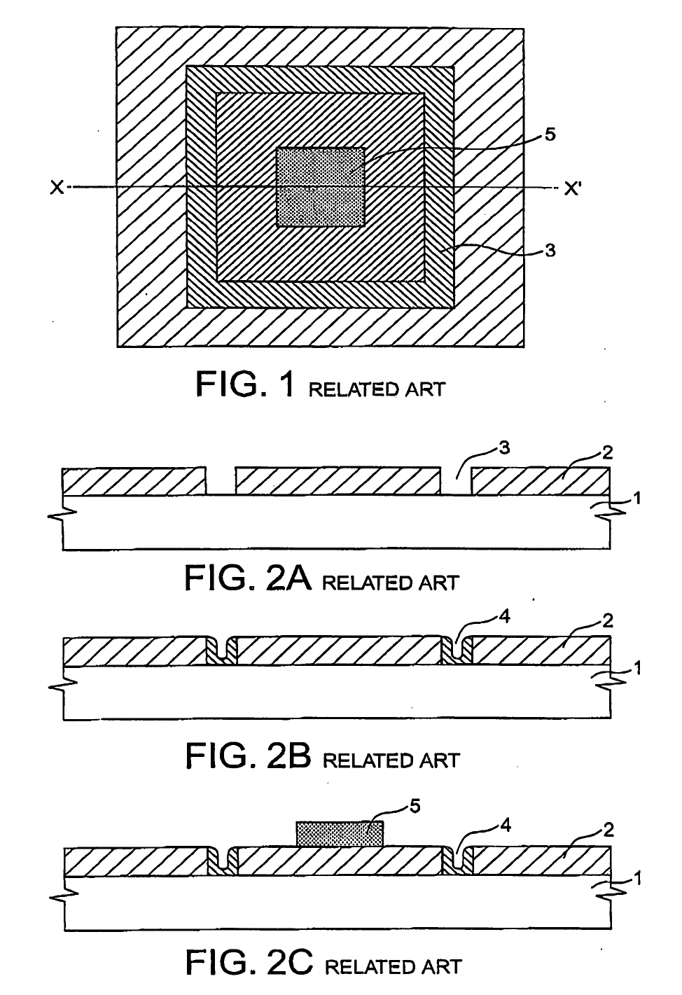

### DETAILED DESCRIPTION OF THE PREFERRED EMBODIMENTS

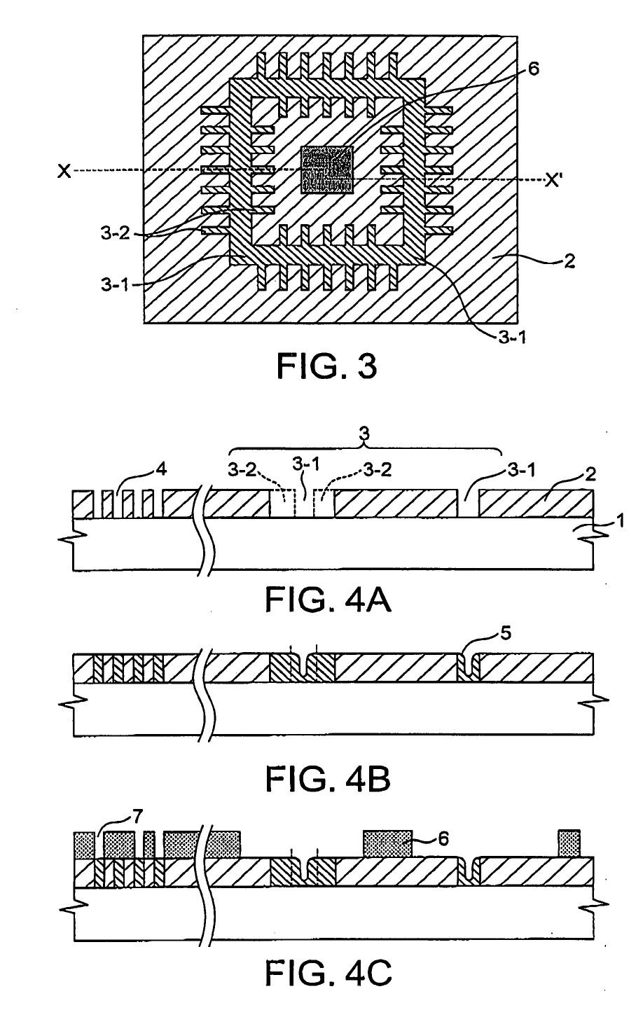

A first embodiment of the present invention will be described below with reference to FIGS. 3 to 4C. FIG. 3 is a plan view showing an overlay measurement mark according to the first embodiment, and FIGS. 4A to 4C are cross-sectional views taken along line X-X′ in FIG. 3 to show a process of forming the overlay measurement mark. In the present embodiment, a basic overlay measurement mark and a pattern formation method for the overlay measurement mark will be described below. In the first embodiment, the overlay measurement mark is formed as a convex mark, which is produced by digging the vicinity of the overlay measurement mark.

The first embodiment will be described with reference to the plan view of the overlay measurement mark shown in FIG. 3 and the cross-sectional views shown in FIGS. 4A to 4C. As shown in FIG. 4A, an insulating film 2 is deposited on a principal plane of a semiconductor substrate 1. Contact holes are formed in the insulating film 2 by an optical lithography process and an etching process. A semiconductor circuit pattern 4 and an overlay measurement reference mark 3 are opened as the contact holes in the insulating film 2. The reference mark 3 includes a base mark pattern 3-1 and rectangular patterns 3-2 as projection patterns. The base mark pattern 3-1 is formed as a rectangular frame in the insulating film 2 and used as a reference member for measuring overlay positional displacement. The rectangular patterns 3-2 as the projection patterns are located so as to intersect the base mark pattern 3-1.

Each of the semiconductor circuit pattern 4 and the rectangular patterns 3-2 of the formed contact holes should fully be filled over the entire line width with a conductive film 5 serving as contact plugs. Accordingly, the line widths of the circuit pattern 4 and the rectangular patterns 3-2 are designed to be not more than two times the film thickness of the deposited conductive film 5. Since a step height is needed in order to reflect light for measurement of overlay positional displacement, the line width of the base mark pattern 3-1 is designed to be more than two times the film thickness of the conductive film 5. As a result, the semiconductor circuit pattern 4 and the rectangular patterns 3-2 are fully filled with the conductive film 5. Since the semiconductor circuit pattern 4 and the rectangular patterns 3-2 have no step height, light is not reflected from the semiconductor circuit pattern 4 and the rectangular patterns 3-2. On the other hand, the base mark pattern 3-1 is not fully filled with the conductive film 5. Thus, the base mark pattern 3-1 has a recessed portion formed therein, and light is reflected from the recessed step portion of the base mark pattern 3-1.

Next, as shown in FIG. 4B, a conductive film 5 is deposited on the semiconductor substrate having the contact holes by a deposition apparatus. The conductive film 5 is flattened by CMP. As described above, the circuit pattern 4 and the rectangular patterns 3-2 are fully filled with the conductive film 5 while the base mark pattern 3-1 is not fully filled with the conductive film 5. Upon the CMP, pressure may be applied to the conductive film 5 in the base mark pattern 3-1 of the overlay measurement mark so as to cause separation of the conductive film 5. Only one side of the conductive film on sidewalls of the base mark pattern 3-1 is brought into contact with the sidewalls, and the other side is not brought into contact with the sidewalls. Accordingly, separation of the conductive film is likely to be caused in the base mark pattern 3-1. On the other hand, three sides of the conductive film 5 filled In the rectangular patterns 3-2 are surrounded by the sidewalls of the rectangular patterns 3-2, so that film separation is not caused in the rectangular patterns 3-2. Therefore, the rectangular patterns 3-2 are used as a reinforcement for preventing separation of the conductive film 5 in the base mark pattern 3-1. Thus, it is possible to form a desired reference mark for overlay measurement.

Then, as shown in FIG. 4C, an overlay exposure function of an exposure apparatus used for optical lithography is used to form an overlay mark 6 to be measured and a circuit pattern 7 on the semiconductor substrate 1. With this structure, the amount of overlay positional displacement between the reference mark 3 and the overlay mark 6 is measured. When the amount of overlay positional displacement was measured by Archer 10 (an overlay measurement apparatus (not shown) manufactured by KLA Tencor Corp), there was no separation of marks, so that overlay measurement could be performed without any troubles. Thus, the amount of positional displacement between the reference mark 3 and the overlay mark 6 is measured by an overlay measurement apparatus, and an overlay correction value is outputted to improve the precision. The overlay correction value is fed back to an exposure apparatus used for exposure of patterns. In this manner, pattern formation can be performed at a high overlay precision,

The reference mark 3 of the overlay measurement mark includes the base mark pattern 3-1 and the rectangular patterns 3-2 as projection patterns positioned so as to intersect the base mark pattern 3-1. In the illustrated example, inner rectangular patterns 3-2 extending inward and outer rectangular patterns 3-2 extending outward are located as the projection patterns so as to intersect the base mark pattern 3-1. For the sake of brevity, some portions of inner rectangular patterns are not illustrated at inner corner areas in FIG. 3. Each of the inner rectangular patterns 3-2 and the outer rectangular patterns 3-2 may be arranged at desired intervals. Furthermore, the inner rectangular patterns 3-2 and the outer rectangular patterns 3-2 may be designed so as to have uneven sizes and may not be arranged at equal intervals. The position and number of the rectangular patterns 3-2 may arbitrarily be designed as long as the rectangular patterns 3-2 have such a line width that they can effectively serve as a reinforcement against film separation in the base mark pattern 3-1. Since the reference mark 3 of the overlay measurement mark includes the rectangular patterns 3-2 serving as a reinforcement, it is possible to prevent film separation.

As described above, in the present embodiment, the base mark pattern 3-1 and the rectangular patterns 3-2 are provided as the reference mark of the overlay measurement mark. The rectangular patterns 3-2, which are added to each side of the base mark pattern 3-1, are small in size and are fully filled with the conductive film 5. Accordingly, the rectangular patterns 3-2 can serve as a reinforcement for preventing film separation. As a result, it is possible to form a desired reference mark for overlay measurement. The amount of overlay positional displacement between the reference mark 3 and the overlay mark 6 is outputted as an overlay correction value. The overlay correction value is fed back to the exposure apparatus used for exposure of patterns, so that pattern formation can be performed at a high overlay precision. According to the present invention, it is possible to manufacture an ultra large scale integrated circuit (ULSI) device having a fine dimension.

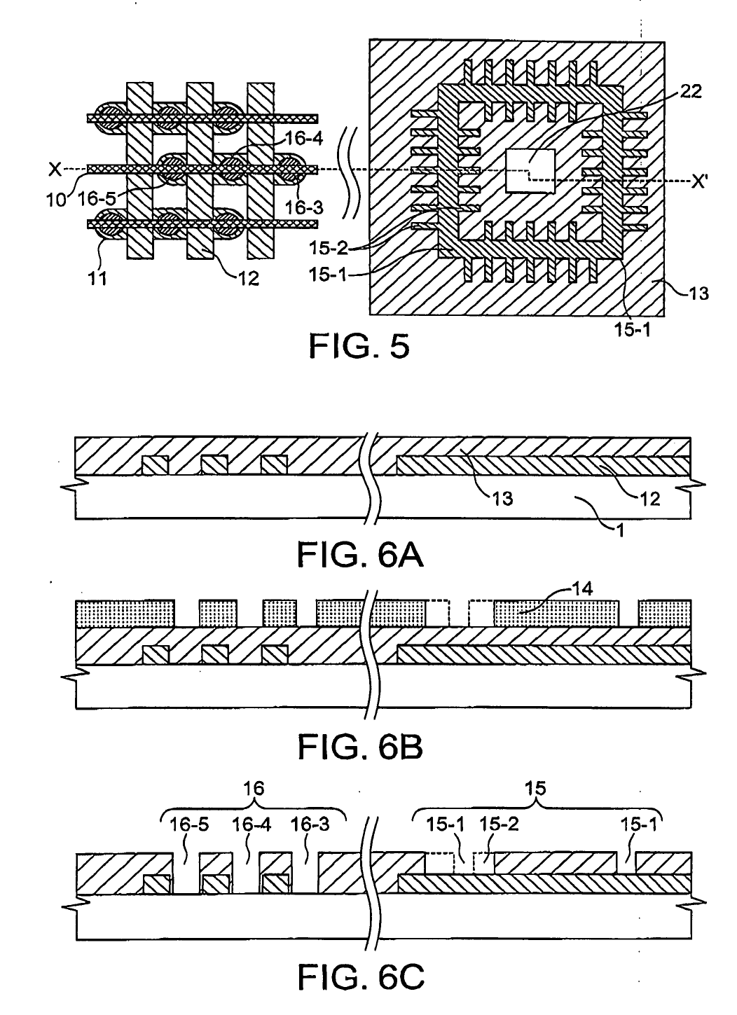

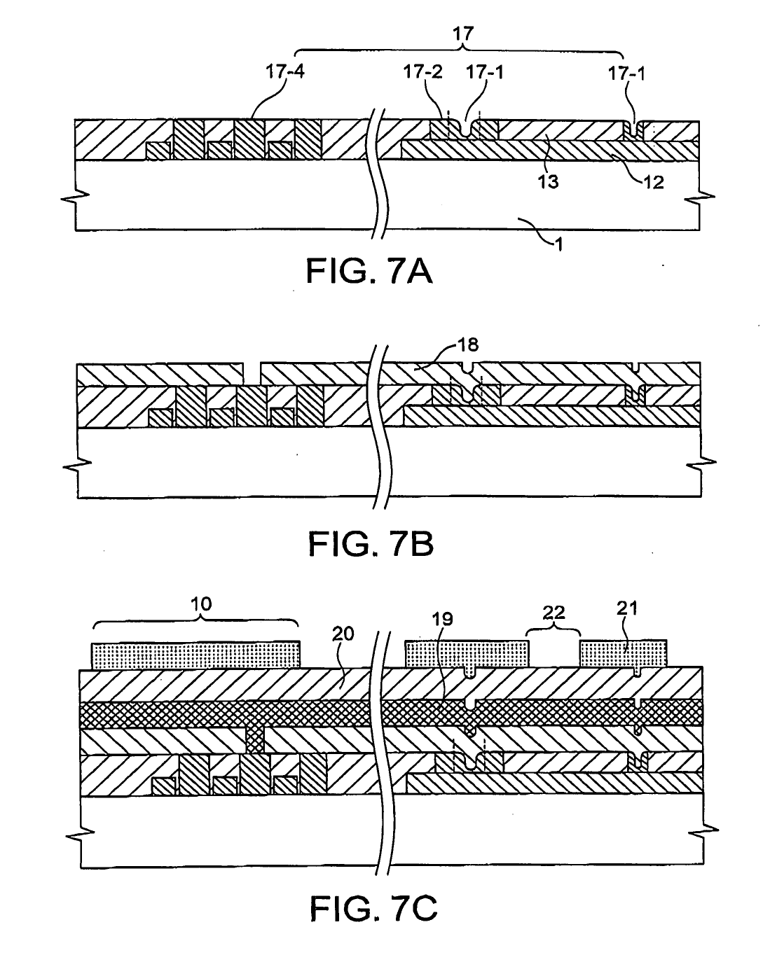

A second embodiment of the present invention will be described below with reference to FIGS. 5 to 7C. FIG. 5 is a plan view showing an overlay measurement mark according to the second embodiment, and FIGS. 6A to 6C and 7A to 7C are cross-sectional views taken along line X-X′ in FIG. 5 to show a process of forming the overlay measurement mark. The present embodiment is an example in which an overlay measurement mark is applied to a dynamic random access memory (DRAM) as a semiconductor device. The overlay measurement mark is formed as a convex mark, which is produced by digging the vicinity of the overlay measurement mark.

FIG. 5 shows a memory cell on the left side and an overlay measurement mark on the right side. The DRAM memory cell on the left side includes devise isolation layers 11, word lines 12 as gate electrodes, conduction contact holes 16, and bit lines 10 on a semiconductor substrate 1. The overlay measurement mark on the right side is used to achieve an accurate overlay of the memory cell. Only processes relating to the essentials of the present invention will be described below, and other details will be omitted from the description.

As shown in FIG. 6A, after a sidewall nitride film (not shown) is formed on a semiconductor substrate 1 on which word lines 12 are formed, an Insulating film 13 is deposited thereon. Then, as shown in FIG. 6B, a resist 14 is patterned by an optical lithography process.

As shown in FIG. 6C, contact holes 15 and 16 are opened in the insulating film 13 by etching. The contact hole 15 serves as a reference mark 15 of the overlay measurement mark and includes a base mark pattern 15-1 in the form of a rectangular frame and rectangular patterns 15-2 as projection patterns. The contact hole 16 includes holes 16-3, 16-5, and 164 as conduction contacts of a circuit pattern and bit lines.

The base mark pattern 15-1 is formed by a rectangular frame hole having an outer shape of 20-μm square and a line width of 4 μm. The rectangular patterns 15-2 are disposed as projection patterns so as to intersect the base mark pattern 15-1. Each of the rectangular patterns 15-2 has a projection width of 0.3 μm and a projection length of 1 μm. The rectangular patterns 15-2 are arranged at pitch intervals of 1.5 μm. The line width of the rectangular pattern 15-2 is designed to be not more than two times the film thickness of polycrystalline silicon, which is formed by a subsequent process, so that the rectangular patterns 15-2 are fully filled with the polycrystalline silicon. As with the first embodiment, the rectangular patterns 15-2 may be designed so as to have uneven sizes and may not be arranged at equal intervals. The position and number of the rectangular patterns 15-2 may arbitrarily be designed as long as the rectangular patterns 15-2 have such a size that they can effectively serve as a reinforcement against separation of the film in the base mark pattern 15-1. Thus, the reference mark 15 of the overlay measurement mark is formed by the base mark pattern 15-1 and the rectangular patterns 15-2.

Then, as shown in FIG. 7A, a P-doped polycrystalline silicon: 17 is deposited with a thickness of 0.3 μm to provide conduction contacts. The polycrystalline silicon 17 on the word lines is removed and flattened by CMP. In this manner, the conduction contacts 16-3, 16-4, and 16-5 are filled with the polycrystalline silicon 17. The rectangular patterns 15-2 as the projection patterns of the reference mark 15 are fully filled with the polycrystalline silicon 17-2. The base mark patterns 15-1 are partially filled with the polycrystalline silicon 17-1 so that a recessed portion is formed at a central portion of the base mark pattern 15-1. Since the rectangular patterns 15-2 are fully filled with the polycrystalline silicon 17-2, the rectangular patterns 15-2 can serve as a reinforcement against film separation. Accordingly, the polycrystalline silicon 17-2 is not separated on sidewalls of the base mark pattern 15-1.

Subsequently, as shown in FIG. 7B, an interlayer oxide film 18 is formed with a thickness of 0.2 μm, and conduction contacts are opened in the interlayer oxide film 18 by an optical lithography process and an etching process. Next, a heavy metal film such as W is formed by sputtering so as to connect the conduction contacts. In the same manner as the above process, portions other than the contact holes are removed by CMP. Furthermore, a tungsten (W) film 19 as bit lines 10 is deposited with a thickness of 0.05 μm by sputtering. A nitride film and an oxide film are formed as a hard mask film 20 with a total thickness of 0.3 μm.

Then a resist pattern 10 of the bit lines and a resist pattern 22 of the overlay mark to be measured are formed with a resist 21 by an optical lithography process (FIG. 7C). For the sake of brevity, it is assumed that the resist pattern 10 forms the bit lines and that the resist pattern 22 forms the overlay mark to be measured.

The overlay positional displacement between the reference mark 15 and the overlay mark 22 is measured. When the amount of overlay positional displacement was measured by Archer 10 (an overlay measurement device (not shown) manufactured by KLA Tencor Corp), there was no film separation in the reference mark, so that overlay measurement could be performed without any troubles. The measurement value of the positional displacement was utilized. Specifically, a correction value of the positional displacement was fed back to an exposure apparatus (an aligner) used for an optical lithography process of a bit line pattern, particularly exposure of patterns. As a result, pattern formation could be performed at a high overlay precision.

In the present embodiment, the overlay measurement mark is applied to a manufacturing process of a DRAM. The reference mark of the overlay measurement mark includes the base mark pattern 15-1 and the rectangular patterns 15-2 as projection patterns disposed so as to intersect the base mark pattern 15-1. The rectangular patterns 15-2, which are added to each side of the base mark pattern 15-1, are small in size and are fully filled with the conductive film 17. Accordingly, the rectangular patterns 15-2 can serve as a reinforcement for preventing separation of the conductive film in the base mark pattern 15-1. As a result, it is possible to form a desired reference mark for overlay measurement. The amount of overlay positional displacement between the reference mark and the overlay mark is outputted as an overlay correction value. The overlay correction value is fed back to the exposure apparatus (aligner) used for exposure of patterns, so that pattern formation can be performed at a high overlay precision. According to the present invention, it is possible to manufacture an ultra large scale integrated circuit (ULSI) device having a fine dimension.

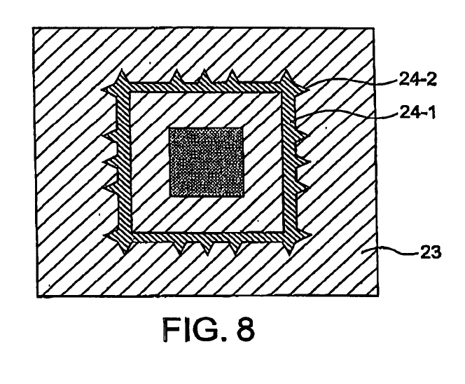

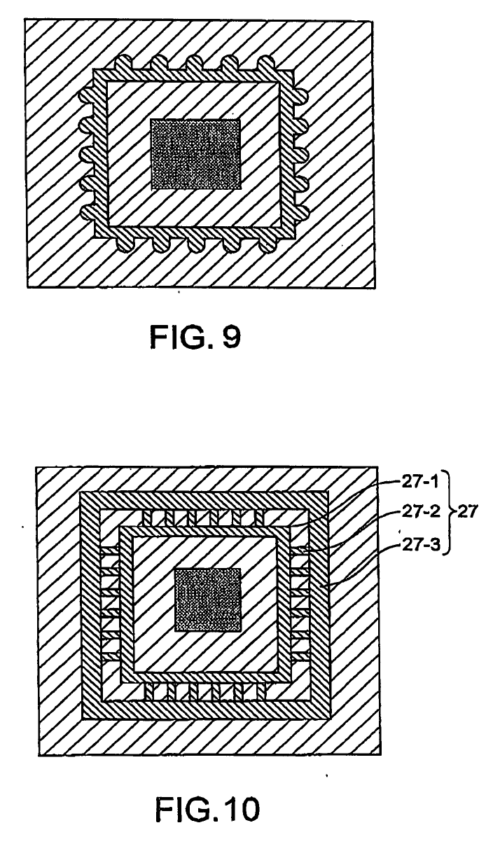

A third embodiment of the present invention will be described below with reference to FIGS. 8 to 10. FIG. 8 is a plan view showing an overlay measurement mark using triangular patterns as projection patterns. FIG. 9 is a plan view showing a variation of the overlay measurement mark, which uses semicircular patterns as projection patterns. FIG. 10 is a plan view showing another variation of the overlay measurement mark, which uses bridge-shaped patterns as projection patterns. In the present embodiment, the overlay measurement mark is formed as a concave mark, which is produced by removing deposition of a reference mark.

The overlay measurement mark shown in FIG. 8 uses triangular patterns as projection patterns.

As shown in FIG. 8, an insulating film 23 is deposited on a semiconductor substrate 1, and contact holes 24-1 and 24-2 are formed in the insulating film 23 by an optical lithography process and an etching process. The contact hole 24-1 has a rectangular shape and is to be a base mark pattern. Each of the contact holes 24-2 has a triangular pattern located on each side of the rectangular base mark pattern 24-1 and is to be a projection pattern. Bases of the triangular patterns 24-2 are held in contact with each side of the rectangular base mark pattern 24-1. The size of the base of the triangular pattern 24-2 is designed to be not more than two times the film thickness of a conductive film to be deposited. Thus, the triangular patterns 24-2 are fine patterns.

FIG. 9 shows an overlay measurement mark using semicircular patterns as projection patterns. Projecting semicircular patterns are provided as a reference mark along each side of a rectangular base mark pattern. Centers of the semicircular patterns are held in contact with each side of the rectangular base mark pattern. The diameter of the semicircular pattern is designed to be not more than two times the film thickness of a film to be deposited. Thus, the semicircular patterns are fine patterns. The semicircular patterns are fully filled with a film deposited in a subsequent process. Accordingly, the semicircular patterns can serve as a reinforcement for preventing film separation.

Furthermore, FIG. 10 shows an overlay measurement mark having projection patterns in the form of a bridge. In this example, the reference mark used for overlay measurement includes double lines of base mark pattern portions. Specifically, the reference mark includes an inner base mark pattern portion 27-1 and an outer base mark pattern portion 27-3, which are used for measurement. The inner base mark pattern portion 27-1 is formed as a concave mark while the outer base mark pattern portion 27-3 is formed as a convex mark. Projection patterns 27-2 are provided so as to interconnect these two base mark pattern portions. The projection patterns 27-2 are referred to as bridge-shaped patterns because the projection patterns 27-2 are provided so as to bridge a space between the two base mark pattern portions.

In this example, the projection patterns are rectangular. However, the projection patterns may be semicircular or triangular. Further, the projection patterns may intersect the outer base mark pattern 27-3 so as to extend outward from the outer base mark pattern 27-3. The line width of the rectangular pattern 27-2 is designed to be not more than two times the thickness of a film to be deposited in a subsequent process. Thus, the rectangular patterns 27-2 are fine patterns. The rectangular patterns 27-2 are fully filled with the deposited film. Thus, since the rectangular patterns 27-2 are small in size and are fully filled with the deposited film, the rectangular patterns 27-2 can serve as a reinforcement for preventing film separation on sidewalls of the two base mark pattern portions 27-1 and 27-3.

Thus, the projection patterns can have various shapes in order to prevent film separation on sidewalls of the base mark pattern of the overlay measurement mark. Further, when an overlay measurement mark has doubled base mark pattern portions or a plurality of base mark pattern portions, a bridge-shaped projection pattern can be used to prevent film separation. Furthermore, the projection patterns disposed on each side of an overlay measurement mark may have different shapes. The size and number of the projection patterns and intervals between the projection patterns may arbitrarily be designed as long as the projection patterns are effective in preventing film separation. Furthermore, the projection patterns may intersect each other.

As described above, when fine projection patterns are added to each side of a base mark pattern of a reference mark, film separation in an overlay measurement mark can be prevented. With use of the overlay measurement mark having no film separation, overlay positional displacement can be measured precisely and fed back to the exposure apparatus (the aligner) so that pattern formation can be performed at a high overlay precision. According to the present invention, it is possible to manufacture an ultra large scale integrated circuit (ULSI) device having a fine dimension.

In the above embodiments, the present invention has been described in connection with a reference mark of an overlay measurement mark. However, the present invention can also be used to prevent film separation of an exposure alignment mark used for exposure. When the present invention is used for an exposure alignment mark, it is possible to maintain an exposure alignment precision and improve an alignment precision. As a matter of course, the present invention can be used for an overlay mark to be measured. Although the second embodiment relates to a method of forming an overlay measurement mark for bit lines, the present invention is applicable to other circuit pattern formation processes. The present invention is also applicable to a manufacturing process of semiconductor devices other than a DRAM. Although optical lithography is used in the above embodiments, the present invention can also be applied to lithography technology requiring an overlay other than optical lithography.

Although certain preferred embodiments of the present invention have been shown and described in detail, it should be understood that the present invention is not limited to the illustrated embodiments and that the embodiments can be modified in various ways. Combinations of the embodiments are not limited, and any combinations of the embodiments can be made. As a matter of course, various changes and modifications may be made therein without departing from the scope of the present invention and included in the scope of the present invention.

1. An overlay measurement mark, comprising:
a base mark pattern; and
a projection pattern in addition to the base mark pattern.

2. The overlay measurement mark according to claim 1, wherein: the projection pattern is held in contact with the base mark pattern.

3. The overlay measurement mark according to claim 2, wherein: the projection pattern has a width not more than two times a thickness of a film to be deposited in a deposition process after patterning.

4. The overlay measurement mark according to claim 3, wherein: the projection pattern comprises a rectangular pattern provided so as to intersect the base mark pattern.

5. The overlay measurement mark according to claim 3, wherein: the projection pattern comprises a triangular pattern having a base provided on a portion of one side of the base mark pattern.

6. The overlay measurement mark according to claim 3, wherein: the projection pattern comprises a semicircular pattern having a diameter passing through a portion of one side of the base mark pattern.

7. The overlay measurement mark according to claim 3, wherein: the base mark pattern includes a plurality of base mark pattern portions, the projection pattern interconnecting adjacent base mark pattern portions.

8. A method of forming a pattern for an overlay measurement mark, comprising:
forming a reference mark including a base mark pattern and a projection pattern in addition to the base mark pattern:
filling the projection pattern: and
forming an overlay mark to be measured.

9. A semiconductor device manufactured by using the overlay measurement mark according to claim 1.

10. A semiconductor device manufactured by using the pattern formation method according to claim 8.

11. A semiconductor device manufactured by using the overlay measurement mark according to claim 2.

12. A semiconductor device manufactured by using the overlay measurement mark according to claim 3.

13. A semiconductor device manufactured by using the overlay measurement mark according to claim 4.

14. A semiconductor device manufactured by using the overlay measurement mark according to claim 5.

15. A semiconductor device manufactured by using the overlay measurement mark according to claim 6.

16. A semiconductor device manufactured by using the overlay measurement mark according to claim 7.
